(19) United States
(12) Patent Application Publication
(10) Pub. No.: US 2010/0061062 A1
(43) Pub. Date: Mar. 11, 2010

(54) MULTI-ORIENTATIONAL COOLING SYSTEM WITH A BUBBLE PUMP

(75) Inventors: Henry Madsen, Allerod (DK); Henrik Olsen, Fredensborg (DK)

Correspondence Address: VOLENTINE & WHITT PLLC, ONE FREEDOM SQUARE, 11951 FREEDOM DRIVE SUITE 1260, RESTON, VA, 20190, US

(73) Assignee: Noise Limit ApS, Allerod (DK)

(21) Appl. No.: 11/813,249

(22) PCT Filed: Dec. 23, 2005
(86) PCT No.: PCT/DK05/00824

§ 371 Date: Aug. 24, 2007

(30) Foreign Application Priority Data
Jan. 3, 2005 (DK) PA 2005 00007

(51) Int. Cl. F28D 15/00; H05K 7/20

(52) U.S. Cl. 361/701; 165/104.33; 165/104.29

(57) ABSTRACT

The present invention relates to a multi-orientational cooling system with a bubble pump for generation of a circulating flow of cooling fluid. The cooling system is a closed cooling system comprising at least one hollow member facilitating flow of the cooling fluid, comprising a first heat-receiving part, a heat-emitting part, and a tubular first part adapted for functioning, in a first angular orientation of the system, as a first bubble pump for generation of a fluid flow in the system and being positioned down-stream the first heat-receiving part, and a tubular second part adapted for functioning, in a second angular orientation of the system, as a second bubble pump for generation of a fluid flow in the system and being positioned downstream the first heat-receiving part.

### FIELD OF THE INVENTION

The present invention relates to a cooling system with a bubble pump for generation of a circulating flow of cooling fluid with improved flexibility with respect to angular orientation of the system in relation to a horizontal axis.

### BACKGROUND OF THE INVENTION

Many systems with a heat-emitting element have attached cooling systems to avoid excessive heating leading to failure of the heat-emitting element. Such systems may be car engines, refrigerators, electronic and electric components, etc.

A characteristic of many of these systems is that they are operated in the same position, but many devices, e.g. electronic devices, such as mobile phones, PDA's, and laptops, are operated in multiple orientations, and at the same time emits a substantial amount of heat.

A cooling unit, particularly for cooling of electronic semiconductor components, is described in US 2003/0 188 858 A1 where the cooling unit comprises a heat-receiving part receiving heat from a heat-emitting element, a cooling liquid transporting heat, and a heat radiator emitting heat to the surroundings. A circulating flow of the cooling liquid is created by decreased density caused by heating and/or vapor bubbles generated by heat received by the heat-receiving part. The system does not comprise a pump for creating a forced flow.

U.S. Pat. No. 5,427,174 discloses a multi-orientational heat exchanger, which comprises a heat-receiving part receiving heat from a heat-emitting element, a cooling liquid comprising a first and a second fluid for transporting heat, and condenser means emitting heat to the surroundings. Capillary forces create a circulating flow of the cooling liquid.

### SUMMARY OF THE INVENTION

There is a need for a cooling system with improved performance for cooling of heat-emitting elements.

Furthermore there is a need for a cooling system that is capable of operating in multiple angular orientations in relation to a horizontal axis.

The above-mentioned and other objects are fulfilled by a closed cooling system for cooling of at least one heat-emitting element by a circulating and evaporating cooling fluid, comprising at least one hollow member facilitating flow of the cooling fluid, comprising a first heat-receiving part for receiving heat from the at least one heat-emitting element, a heat-emitting part for emission of heat absorbed by the heat-receiving part to the surroundings, and a first part adapted for functioning, in a first angular orientation of the system, as a first bubble pump for generation of a fluid flow in the system and being positioned downstream the first heat-receiving part, and a second part adapted for functioning, in a second angular orientation of the system, as a second bubble pump for generation of a fluid flow in the system and being positioned downstream the first heat-receiving part.

Preferably, the first part is a tubular first part interconnecting the first heat-receiving part and the heat-emitting part.

Preferably, the second part is a tubular second part interconnecting the first heat-receiving part and the heat-emitting part.

It is an important advantage of the present invention that the cooling system is capable of operating in at least a first and a second angular orientation wherein the second angular orientation is obtained by rotating the cooling system from the first angular orientation an angle θ around a substantially horizontal axis. The angle θ may be an arbitrary angle, such as around 15°, around 30°, around 45°, around 60°, around 75°, around 90°, around 105°, around 120°, around 135°, around 150°, around 165°, around 180°, around 195°, around 210°, around 225°, around 240°, around 255°, around 270°, around 285°, around 300°, around 315°, around 330°, and around 345°. Typically, the system also operates in any angular orientation between the first and second orientation.

It is an advantage of the present invention that the main part of the cooling fluid in the system has a relatively high rate of flow during operation in different angular orientations, thus providing a more effective cooling system compared to systems where cooling fluid is substantially not moving or has a very low rate of flow in some parts of the system.

Further, in some embodiments of the cooling system according to the invention, there may exist angular orientations and filing levels wherein the system operates only by evaporation or by evaporation and reduced cooling fluid flow. Typically, in these angular orientations the performance of the system is decreased.

It is an important advantage of the present invention that the cooling system does not comprise moving mechanical parts for moving the cooling fluid, such as pumps with moving parts. This reduces the cost and increases the reliability of the system.

It is a further advantage of the present invention that the cooling system is substantially silent.

It is a still further advantage of the present invention that the cooling system is capable of removing large amounts of generated heat per unit area, such as more than 15 W/cm², e.g. more than 20 W/cm², e.g. more than 30 W/cm², such as more than 40 W/cm², e.g. more than 50 W/cm², such as about 75 W/cm², such as about 100 W/cm², such as about 125 W/cm², etc., e.g. resulting in a temperature increase below 40° C. above ambient.

The first part and the second part, which are adapted for functioning as a bubble pump in different angular orientations create a high flow rate of cooling fluid in the respective part functioning as a bubble pump. Thus a high flow rate of cooling fluid in the system is created compared to e.g. a system driven as a thermo siphon. Further, the first part and the second part, which are adapted for functioning as a bubble pump in different angular orientations, provide circulation of liquid cooling fluid enabling cooling of liquid cooling fluid. The liquid cooling fluid may have a large heat capacity.

The cooling system according to the present invention may comprise a third part adapted for functioning, in a third angular orientation of the system, as a third bubble pump for generation of a fluid flow in the system, the third part being positioned downstream the heat-receiving part.

The cooling system according to the present invention may comprise a fourth part adapted for functioning, in a fourth angular orientation of the system, as a fourth bubble pump for generation of a fluid flow in the system, the fourth part being positioned downstream the heat-receiving part.

Preferably, the parts adapted for functioning as a bubble pump in specific respective angular orientations are tubular. The tubular parts may have cross sections of arbitrary shape, such as rectangular, quadratic, or round, preferably substantially circular, or substantially oval, or any combination hereof. Furthermore, the parts adapted for functioning as a bubble pump in specific respective angular orientations may interconnect the first heat-receiving part and the heat-emitting part.

In a bubble pump, gas bubbles, such as vaporized or gaseous cooling fluid, move liquid above the bubbles upward in the bubble pump so that the motive forces of the bubbles generate a flow of both liquid and gaseous cooling fluid.

The efficiency of a bubble pump, i.e. the amount of liquid transported through the bubble pump as a function of time, is i.a. determined by the internal diameter of the bubble pump and the properties of the fluid or fluids to be pumped, such as amount and size of the vapor bubbles, viscosity of the fluid(s), etc.

The internal diameter of the parts adapted for functioning as a bubble pump must be sufficiently large to provide a suitable flow capacity. Preferably, the vapor bubbles in a functioning bubble pump attains a size with a cross section substantially equal to the internal diameter of the bubble pump to provide suitable pumping of liquid through the bubble pump.

The internal diameter of the parts adapted for functioning as a bubble pump may range from around 1 mm to around 30 mm, such as from around 2 mm to around 20 mm, from around 3 mm to around 18 mm, from around 5 mm to around 15 mm, from around 7 mm to around 13 mm, from around 8 mm to around 12 mm, e.g. equal to app. 10 mm.

The area of the interior cross section of the first and second parts may range from around 0.75 mm² to around 700 mm², such as from around 3 mm² to around 300 mm², from around 7 mm² to around 250 mm², from around 20 mm² to around 175 mm², from around 40 mm² to around 130 mm², from around 50 mm² to around 115 mm², e.g. around 75 mm². The area of different interior cross sections of the first or second parts may vary.

Preferably, the part adapted for functioning as a bubble pump in an operating angular orientation partly extends substantially linearly along a substantially vertical axis in the operating angular orientation in question. The part functioning as a bubble pump in one operating angular orientation may also operate as a bubble pump in another operating angular orientation, e.g. when the cooling system is rotated around a horizontal axis with respect to the vertical axis in an angle from 0° to around 135° such as from 0° to around 115°, from 0° to around 90°, from 0° to around 60°, from 0° to around 45°, from 0° to around 25°, from 0° to around 15°, from 0° to around 5°.

Accordingly, the parts adapted for functioning as a bubble pump may be designed so that the cooling system can be operated in an arbitrary angular orientation.

The length of the part adapted for functioning as a bubble pump in a specific angular orientation of the system is determined to obtain the desired pumping or flow capacity for the part in question. Preferably, the length of the part in question is larger than the internal diameter of the part in question. The length of the part in question may range from around 3 mm to around 200 mm, such as from around 5 mm to 180 mm, from around 8 mm to around 150 mm, from around 10 mm to around 100 mm, from around 20 mm to around 80 mm, e.g. around 30 mm, around 40 mm, around 50 mm, or around 60 mm.

Preferably, at least one of the parts adapted for functioning as a bubble pump in a respective angular orientation of the system has an outlet above the liquid level in the cooling system in that orientation for substantially prevention of reflux of fluid in the system.

The liquid level in the cooling system is the liquid level in the heat-emitting part.

It is believed that positioning of the outlet of the part or parts adapted for functioning as a bubble pump in a respective angular orientation of the system above the liquid level in the system lowers the resistance against the liquid flow experienced by the bubbles in the part or parts operating as a bubble pump. Thus, provision of an outlet above the liquid level in the system provides increased circulation of cooling fluid leading to improved cooling capability of the cooling system.

In one embodiment of the invention, an outlet of the first or second part adapted for functioning as a bubble pump in a respective angular orientation of the system is positioned in the heat-emitting part in such a way that the outlet of the first or second part in an operating angular orientation of the cooling system resides above the liquid level in the heat-emitting part and thereby above the liquid level in the cooling system. As already mentioned, this enhances the efficiency of the part operating as a bubble pump, since reflux flow of fluid back into the part comprising the part functioning as a bubble pump is avoided. It is further believed that this positioning of the outlet lowers the resistance against the liquid flow experienced by the bubbles in the first or second part. Thereby the circulating flow in the system is increased, providing improved heat-transfer and thus improved cooling.

The outlet may be formed to facilitate the outflow of liquid from the part adapted for functioning as a bubble pump, e.g. the outlet may be chamfered.

The outlet of the first part in the first operating angular orientation may operate as an inlet of the first part in the second operating angular orientation. Accordingly the outlet of the second part in the second operating angular orientation may operate as an inlet of the second part in the first operating angular orientation. In the first operating angular orientation, the cooling fluid flow may be in the opposite direction of the cooling fluid flow in the second operating angular orientation.

The first part may in the second operating angular orientation operate as an inlet pipe to the heat-receiving part, and the second part may in the first operating angular orientation operate as an inlet pipe to the heat-receiving part.

The heat-emitting part may comprise a portion adapted to operate as a condenser and a portion adapted to operate as a radiator. The portion adapted to operate as a radiator emits heat to the surroundings by cooling of cooling fluid in liquid state and the portion adapted to operate as a condenser emits heat to the surroundings by condensing of gaseous cooling fluid, i.e. cooling fluid in vapor form. Thus the portion adapted to operate as a condenser of a heat-emitting part can be defined as the portion of the heat-emitting part that resides above the liquid level in the system during operation. A portion of the first heat-emitting part may operate as radiator in one operating angular orientation of the cooling system and/or as condenser in another operating angular orientation of the cooling system.

The heat-emitting part may be formed such that the original concentration ratio of the cooling fluid is substantially reestablished before entrance into the heat-receiving part(s) independent of the design of the portions adapted to operate as condenser and radiator.

The heat-emitting part may be cooled utilizing natural convection, forced convection, or alternatively by an active cooling system, such as a compressor cooler. For example, a power supply unit fan may also be used for forced convection of the cooling system.

The cooling system may further comprise one or more separators to separate vapor and liquid of the cooling fluid. The one or more separators may be an integrated part of the heat-emitting part. The one or more separators may comprise the respective outlets of the first and second parts. The one or more separators may in an operating angular orientation separate the cooling fluid in vapor and liquid and may guide the vapor to the portion adapted to operate as condenser and the liquid to the portion adapted to operate as radiator.

The cooling system may be adapted for cooling of more than one heat-emitting element. For example, the first heat-receiving part may be of a sufficient size to receive heat from more than one heat-emitting element, and/or the cooling system may comprise more than one heat-receiving part. In this case, the heat-receiving parts may each receive heat from one or more heat-emitting elements. The fact that more than one heat-emitting element may be positioned along the heat-receiving part(s) of the cooling system may provide an advantage regarding to economy of space and/or regarding enhanced circulation of the cooling fluid.

The heat-receiving part(s) may comprise a heat-exchanging surface, which is adapted to thermally contact the heat-emitting element. Hereby the cooling system is adapted to receive heat from a heat-emitting element in thermal contact with the heat-exchanging surface. The heat-exchanging surface is typically shaped to correspond to the shape of the heat-emitting element(s) to be cooled. Preferably, the heat-exchanging surface of the heat-receiving part(s) of the cooling system is made of a heat-conducting material, such as aluminum, copper, silver, gold, or alloys comprising one or more of these materials.

Preferably, the first heat-receiving part forms an enclosure having at least a first port and a second port for cooling fluid. Further, the first heat-receiving part may comprise a third port and/or a fourth port for cooling fluid. The first port, second port, third port, and/or the fourth port may function as inlet to or outlet from the first heat-receiving part depending on the direction of cooling fluid flow. In a preferred embodiment of the present invention, the first port is connected to the first part and the second port is connected to the second part.

Advantageously, the heat-emitting element may be integrated with the heat-receiving part(s) to be in direct contact with the cooling fluid of the cooling system. Hereby, the heat exchange between the heat-emitting element to be cooled and the heat-receiving part(s) is optimized. The integration between the heat-emitting element to be cooled and the heat-receiving part(s) of the cooling system may advantageously be performed during the manufacture of the cooling system so that the cooling system is adapted to the heat-emitting element to be cooled and its possible electrical connections to other elements.

Various parts of the at least one hollow member, such as the heat-receiving part(s), part(s) functioning as bubble pump, and/or the heat-emitting part of the cooling system, may comprise a plurality of separated cooling fluid chambers or channels. Such parts may for example be made as a closed, extruded profile forming a plurality of chambers, and the ends of the profile may be connected to the other parts of the cooling system by means of manifolds.

The cooling fluid may consist of a single fluid or comprise two or more fluids. The fluids in the cooling fluid may be soluble within each other.

During operation of the cooling system according to the present invention, the cooling fluid in liquid form may constitute from around 30% to around 95% by volume of the volume of the hollow member, such as from around 50% to around 90% by volume, from around 70% to around 80% by volume preferably around 75% by volume.

The single fluid may be water, ethanol, methanol, CO₂, propane, or ammonia or other fluids having suitable thermal and physical properties, such as a fluorine compound, e.g. 3M® FC-72 and 3M® FC 82 or other suitable fluorine compounds.

In a preferred embodiment of the invention, the cooling fluid comprises two fluids, a first fluid with a low boiling point temperature that boils within the operational temperatures of the at least one heat-emitting element, and a second fluid with a higher boiling point that does not reach its boiling point within these temperatures. The bubbles formed by boiling of the first fluid move the second fluid in the part adapted to function as a bubble pump in an operating angular orientation, thereby generating circulation of the cooling fluid in the system. The second fluid, mainly in liquid form and having a large heat capacity, absorbs and transfers a large amount of heat from the heat-receiving part(s) to the portion of the heat-emitting part, which is adapted to operate as a radiator thereby increasing the cooling capability of the system.

In liquid form, the second fluid maintains good surface contact with the interior surfaces of the heat-receiving part(s) and the portion of the heat-emitting part adapted to operate as a radiator, respectively.

Thus, in the part functioning as a bubble pump in a specific orientation, the first fluid with the lowest boiling point is used to pump the second fluid with the higher boiling point into circulation in the cooling system for transfer of heat from the heat-receiving part(s) to the heat-emitting part.

The fluid with the lowest boiling point is selected so that it boils within the operating temperature range of the heat-emitting element. The fluid with the higher boiling point is selected so that it remains substantially in its liquid form and does not reach its boiling point within the intended operating temperatures of the heat-emitting elements. In the part operating as a bubble pump in an operating angular orientation, the bubbles originally generated in the heat-receiving part(s) move the liquid with the higher boiling point thereby generating a liquid flow through the heat-receiving part(s). The liquid flow increases heat removal from the heat-receiving part(s) due to the high heat capacity of the fluid with the high boiling point.

Further, the liquid flow removes bubbles generated in the heat-receiving part(s) while they are still small thereby avoiding that bubbles isolate the heat-receiving part(s) from the liquid part of the cooling fluid, which would lower heat transfer from the heat-emitting element to the cooling fluid. This type of boiling is generally known as flow boiling. Compared to pool boiling this type of boiling provides an enhanced heat transfer to the cooling fluid. Further, the enhanced flow facilitates the utilization of a cooling fluid comprising two or more fluids with different boiling points in that the improved cooling fluid flow provided by the part or parts functioning as a bubble pump maintains the mixture ratio of the fluids and thereby the boiling point.

Thus, a controlled and effective cooling in at least two operating angular orientations of the cooling system is obtained. The resulting cooling effect is obtained by the combination of absorbing heat by evaporation of the fluid with the lowest boiling point, which evaporates completely or partly, and by heating and removal, mainly without evaporation, of the one or more fluids with a higher boiling point. The fluid(s) with the higher boiling point(s) typically evaporates to a limited extent, however the fluid flow removes heat from the heat-receiving part.

Since the fluid with the highest boiling point typically evaporates to a limited extent only, dry boiling of the system is avoided under intended operational conditions.

According to a preferred embodiment of the invention, the cooling fluid comprises a first fluid with a low boiling point and a second fluid with a high boiling point.

Preferably, the first fluid may comprise ethanol, methanol, acetone, ether, propane, etc., or other fluids also having suitable thermal and physical properties.

In a presently preferred embodiment, the first fluid is ethanol, the cooling fluid comprising between 4% and 96% volume by volume of ethanol, such as from 15% to 45%, from 30% to 40%, preferably about 37%.

The first fluid may be any liquid, which easily vaporizes and which is miscible with or absorbed in water. Such other options are ammonia, the fluorine compounds 3M® FC-72 and 3M® FC 82, and others.

Preferably, the second fluid is water. Water has the advantages that it is cheap, is readily available, and a possible leak will not lead to contamination. Other suitable fluids may be methanol, ethanol, acetone, glycol, propane or other fluids having suitable thermal and physical properties.

According to a preferred embodiment a specific pressure is applied to the cooling system. Thereby the boiling point temperature of the first fluid may be adjusted in a simple way. This has the effect that a wide range of different cooling fluids may be employed for cooling to a given maximum temperature. It is understood that the specific pressure applied to the system is the system pressure when the system is not operating, i.e. when substantially all parts of the system have the same temperature, e.g. room temperature. This specific pressure may advantageously be adjusted during manufacture of the cooling system. When the cooling system is in operation, the cooling fluid will be heated, and typically, the pressure in the system changes.

According to a preferred embodiment the pressure of the cooling system is adjusted in such a way that the boiling point of the first cooling fluid resides within a desired operating temperature range of the cooling system. The pressure in the system is preferably substantially equal to the saturation pressure of the cooling fluid at the actual temperature.

Preferably, the cooling system is substantially evacuated before entrance of the cooling fluid into the cooling system to avoid presence of air or any other undesired gases in the cooling system. Air or undesired gases may react with the selected cooling fluids, and presence of undesired gases may decrease the efficiency of the system by occupying volume in the cooling system. Upon evacuation, the cooling fluid is entered into the cooling system and the system is hermetically sealed.

According to a preferred embodiment of the present invention, the internal volume in the cooling system is substantially filled with cooling fluid in combined liquid and gaseous form, i.e. the content of non-condensable gases, such as N₂, O₂, CO₂, H₂, etc., or other contaminants is minimized, e.g. the content is less than 10% by volume of the internal volume, such as less than 5%, less than 3%, less than 1%, less than 0.1%, or less than 0.01% of the internal volume.

The efficiency of the cooling system is believed to be the higher the lower the content of non-condensable gases, since non-condensable gases do not contribute to the heat transfer from the heat-receiving part(s) to the heat-emitting part.

The term “non-condensable gases” denotes gases, which are not condensable within the operating temperature and operating pressure of the cooling system.

To prevent formation of non-condensable gases after filling of cooling fluid, the cooling fluid may comprise a corrosion inhibitor.

It should be noted that the specific pressure may be equal to or around atmospheric pressure, larger than atmospheric pressure as well as lower than atmospheric pressure depending on the selected cooling fluid and the desired maximum operating temperature of the heat-emitting elements.

The flexibility of pressure adjustment is advantageous, since it may be difficult to find a cooling fluid having the desired boiling point. In certain cases such a cooling fluid may exist, but may have other disadvantages such as high cost, toxicity, etc.

The cooling system is preferably made of a diffusion tight material. By the expression “diffusion tight material” is understood a material that does not entail larger diffusion between the cooling system and the surroundings during the intended lifetime of the system than can be allowed for the system to operate as intended during its entire intended lifetime. If the cooling system is employed in computers, the intended lifetime will typically be in the order of 4-5 years and in special cases down to 2 years or up to 10 years. If different parts of the cooling system are made of different materials, all materials as well as their connections must be diffusion tight. Suitable materials may be copper, silver, aluminum, iron or alloys containing one or more of these materials. Moreover, one or more parts of the cooling system may be made of plastic material, provided that it is made diffusion tight according to the above-mentioned definition of the expression. A metal layer forming part of the plastic material may ensure this, such metal layer may for example be vapor deposited onto the plastic material.

The cooling system may further comprise a window of a material that has a larger permeability for undesired gases than the material(s) of the remaining parts of the cooling system. For example, the window may be hydrogen permeable, and made of e.g. nickel, or an alloy thereof, e.g. an iron-nickel alloy, or palladium or an alloy thereof, e.g. a silver-palladium alloy, or any other metallic or non-metallic materials, such as ceramics, suitable for this purpose. Hereby, the undesired gasses are removed into the atmosphere by diffusion through the window. The window may be positioned adjacent to a connecting piece for entering the cooling fluid into the cooling system. The diffusion of undesired gases may then take place for a period after filling of the cooling system, and at the end of the period the window may be removed together with the connecting piece during final closing of the cooling system.

Further, it may be conceived to add a substance that absorbs the undesired gases in the cooling system, such as gases formed during initial corrosion.

The invention furthermore relates to an electronic device having one or more elements to be cooled during the operation of the electronic device, the electronic device comprising a cooling system according to the invention.

The invention also relates to use of the closed cooling system for cooling of electronic components. Such components may for example be microchips, CPU's, semiconductor devices, etc. in computers or other electronic devices. In particular in the field of cooling of electronic components, the cooling system according to the invention is advantageous, as it is a low noise unit, has no mechanically movable elements and as it is started automatically by the heat, which the electronic components emits.

It should be noted that the expression “cooling fluid” denotes a fluid that is used for cooling, and which either consists of a single fluid or a mixture of two or more fluids.

Throughout the present description, a single fluid denotes a fluid with purity of more than 96% volume by volume.

Furthermore, it should be noted that the cooling system may comprise more than one heat-emitting part comprising a portion adapted to operate as a condenser and/or a portion adapted to operate as a radiator. In such cases the heat-emitting parts may be arranged in series or in parallel or a combination thereof.

It should be noted that parts of the cooling system may be made of rigid pipes or tubes, or pipes that are flexible either due to their design or due to their material. Furthermore, the at least one hollow member may form a suitable arbitrary profile, e.g. round, oval, rectangular, quadratic, or a combination of these, and the internal volume of the at least one hollow member may constitute a single chamber or may be divided into a plurality of chambers.

The heat-receiving part(s) in the figures is shown to be quadrangular, but any heat-receiving part may have different shapes, such as round, oval, rectangular, quadratic or a combination of these. Preferably, the heat-receiving part(s) has a contact surface, which is adapted to the shape of the heat-emitting element(s). Typically, the contact surface is a plane surface. It should be noted that the contact surface of the heat-receiving part(s) is the part of the heat-exchanging surface of the heat-receiving part, which is in contact with the heat-emitting element(s).

Typically, a thermal conductive paste or a thermal conductive pad is placed between the contact surface of the heat-receiving part(s) and the heat-emitting element(s) to enhance heat transfer.

The interior of the heat-receiving part(s) may be provided with fins, ribs, rods, etc. to enhance the contact area between the cooling fluid and the heat-receiving part(s). These contact area-enhancing elements may for example be brazed elements or may be produced by e.g. sintering, casting, pressing, extrusion, or chip cutting.

The interior of the heat-emitting part(s) may be provided with fins, ribs, rods, etc. to enhance the contact area between the cooling fluid and the heat-emitting part(s).

These contact area-enhancing elements may for example be brazed elements or may be produced by e.g. sintering, casting, pressing, extrusion, or chip cutting.

The outside of the heat-emitting part(s) may be provided with fins, ribs, rods, etc. to enhance the contact area between the surroundings and the heat-emitting part(s).

These contact area-enhancing elements may for example be brazed elements or may be produced by e.g. sintering, casting, pressing, extrusion, or chip cutting.

The cooling system according to the invention may advantageously be employed, where low noise cooling is desired, e.g. in portable or stationary computers, electronics, overhead projectors, beamers, air condition systems, etc.

The invention will now be described in further detail with reference to the figures of the drawing, wherein

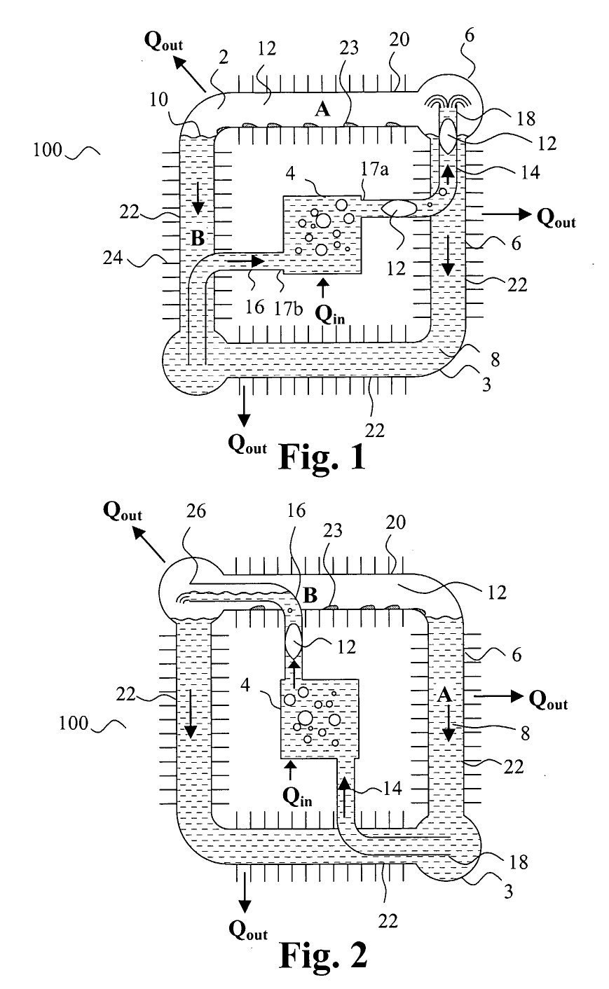

FIG. 1 is a schematic side view of a cooling system according to the present invention,

FIG. 2 is a schematic side view of the cooling system of FIG. 1 rotated about 90° clockwise around an axis perpendicular to the plane of the drawing,

FIG. 3 is a schematic side view of the cooling system of FIG. 1 rotated about 180° clockwise around an axis perpendicular to the plane of the drawing,

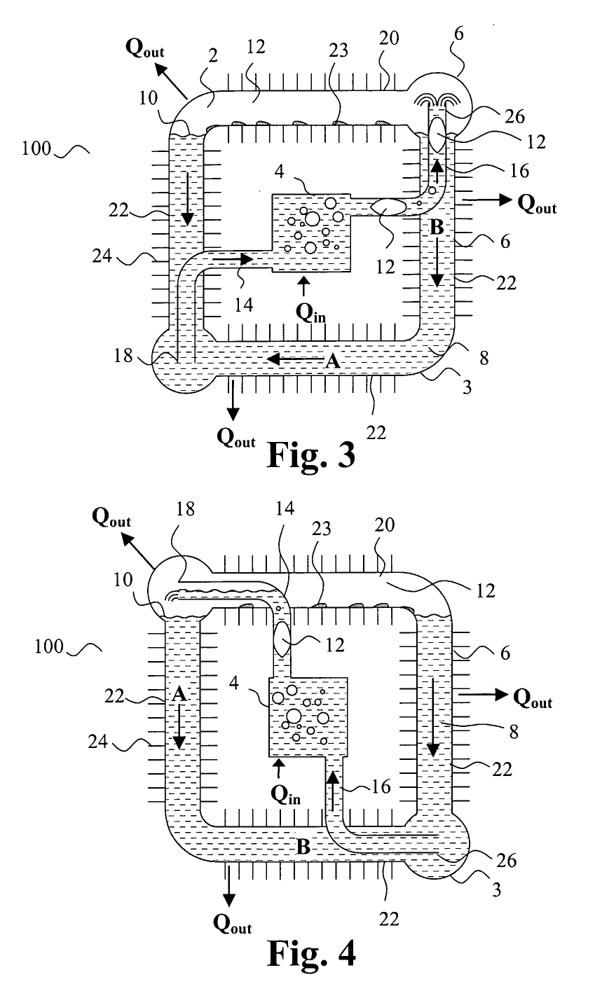

FIG. 4 is a schematic side view of the cooling system of FIG. 1 rotated about 270° clockwise around an axis perpendicular to the plane of the drawing,

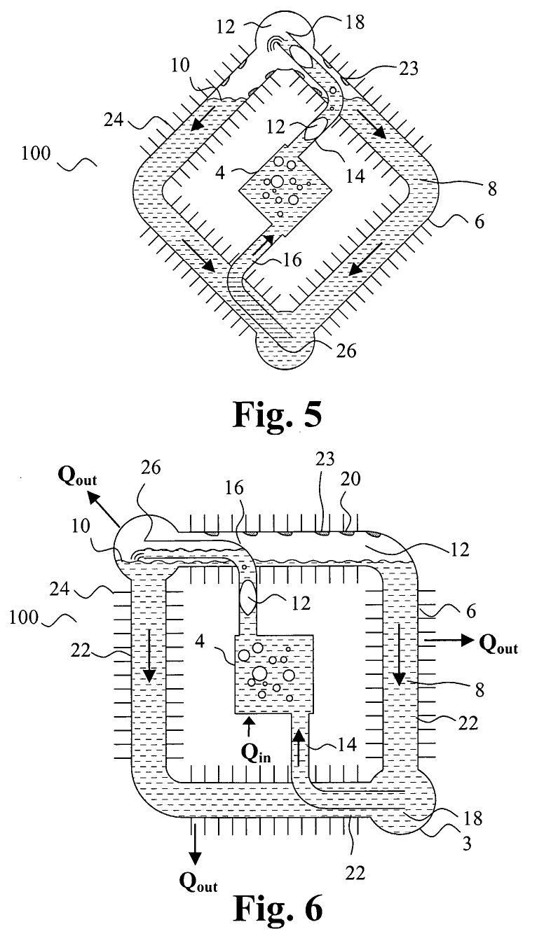

FIG. 5 is a schematic side view of the cooling system of FIG. 1 rotated about 315° clockwise around an axis perpendicular to the plane of the drawing,

FIG. 6 shows the cooling system of FIG. 2, where the liquid level of the system is changed,

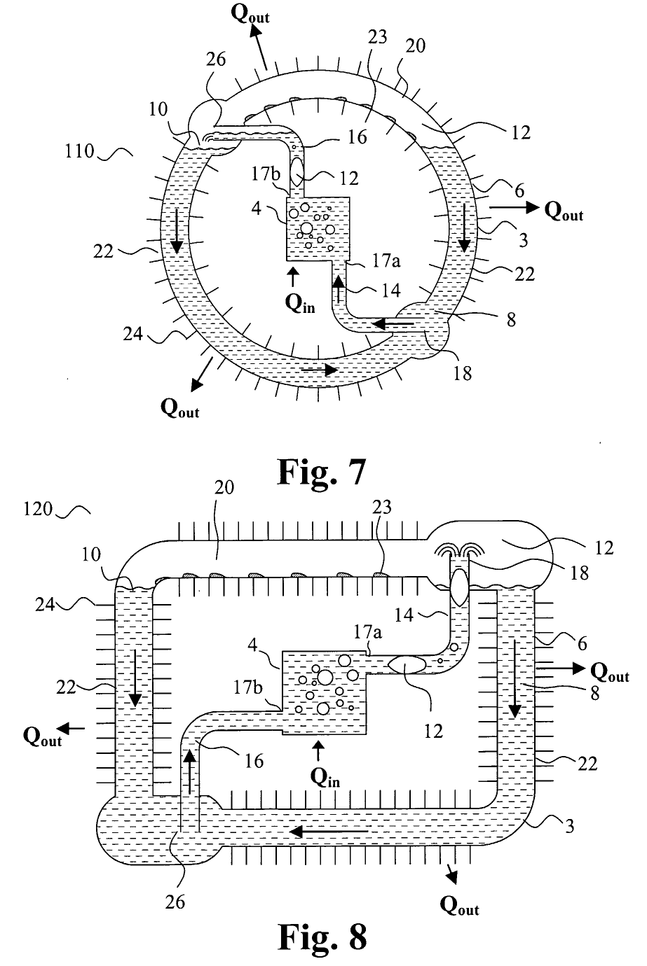

FIG. 7 shows a schematic side view of a second embodiment of the cooling system according to the invention,

FIG. 8 shows a schematic side view of a third embodiment of the cooling system according to the invention,

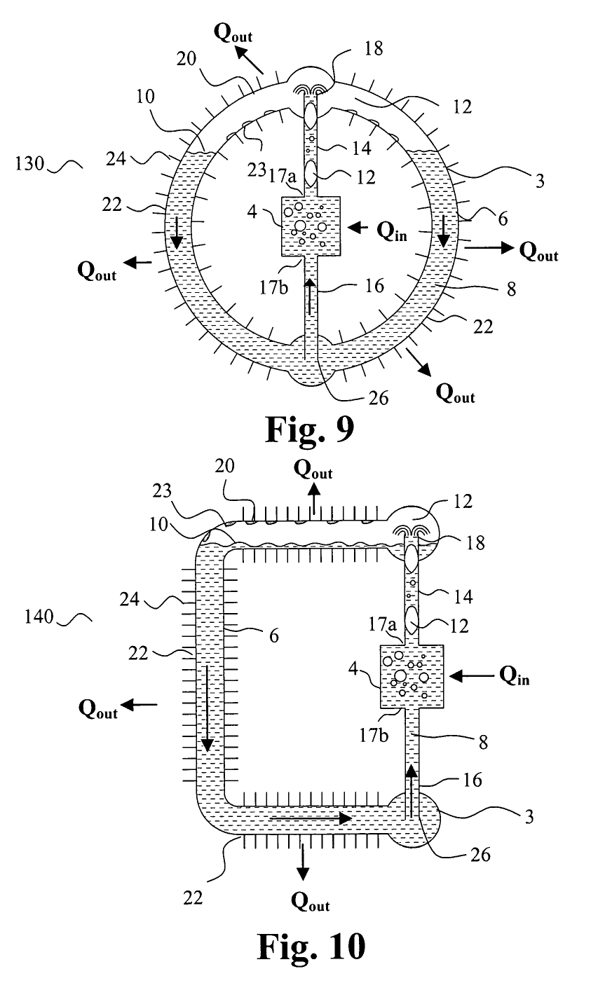

FIG. 9 shows a schematic side view of a fourth embodiment of the cooling system according to the invention,

FIG. 10 shows a schematic side view of a fifth embodiment of the cooling system according to the invention,

FIG. 11 is a schematic side view of the cooling system of FIG. 10 rotated about 180° clockwise around an axis perpendicular to the plane of the drawing,

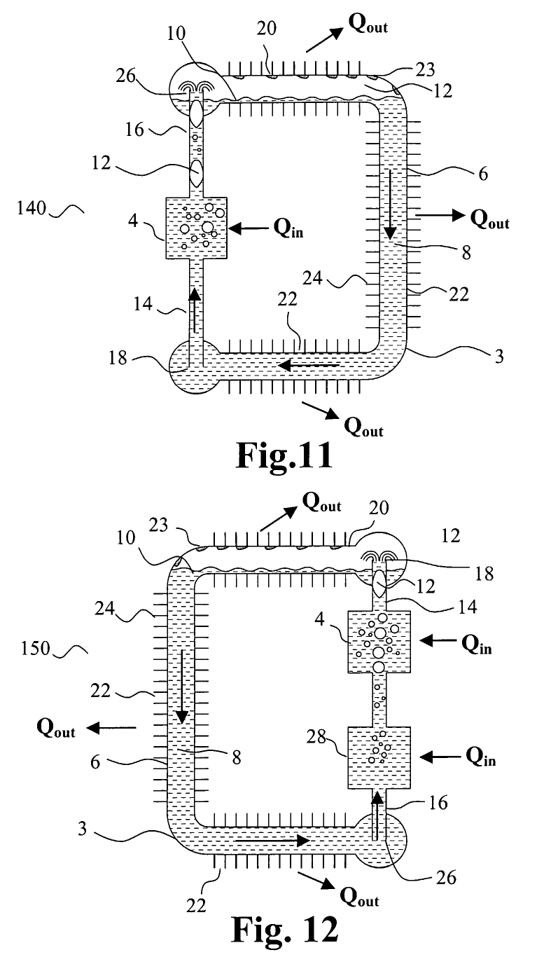

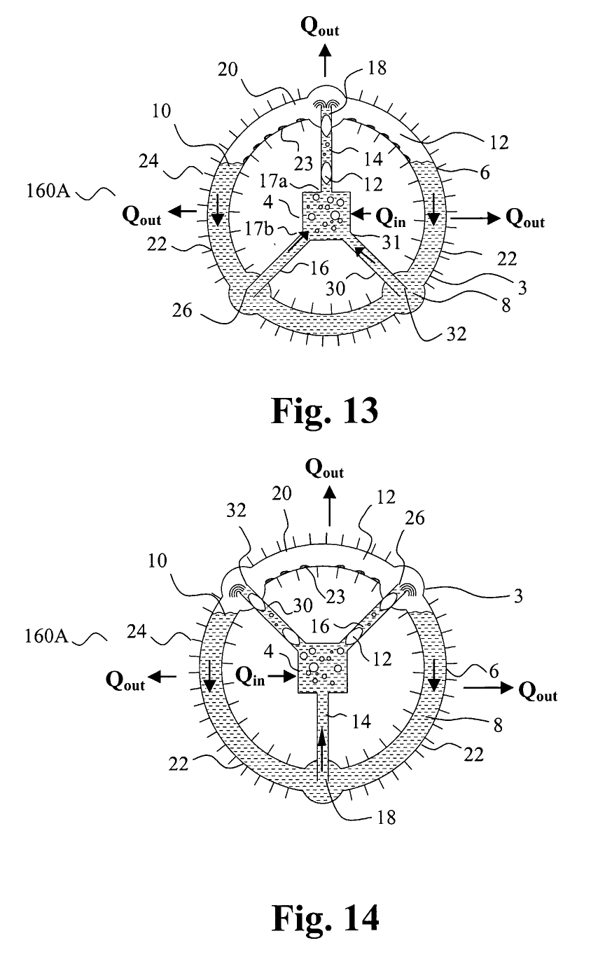

FIG. 12 shows a schematic side view of a sixth embodiment of the cooling system according to the invention,

FIG. 13 shows a schematic side view of a seventh embodiment of the cooling system according to the invention,

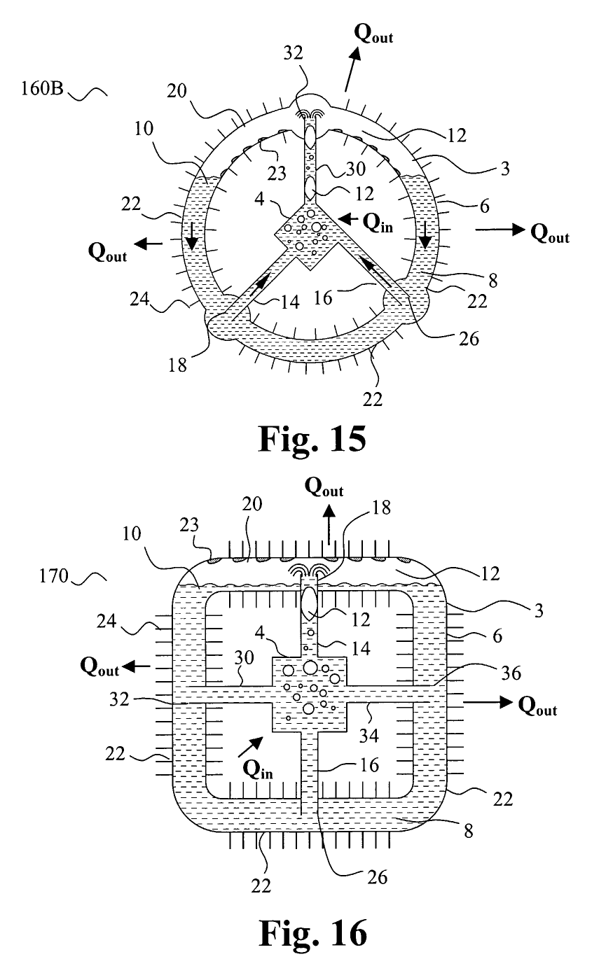

FIG. 14 is a schematic side view of the cooling system of FIG. 13 rotated about 180° clockwise around an axis perpendicular to the plane of the drawing,

FIG. 15 is a schematic side view of an embodiment similar to the cooling system of FIG. 13,

FIG. 16 shows a schematic side view of an eighth embodiment of the cooling system according to the invention,

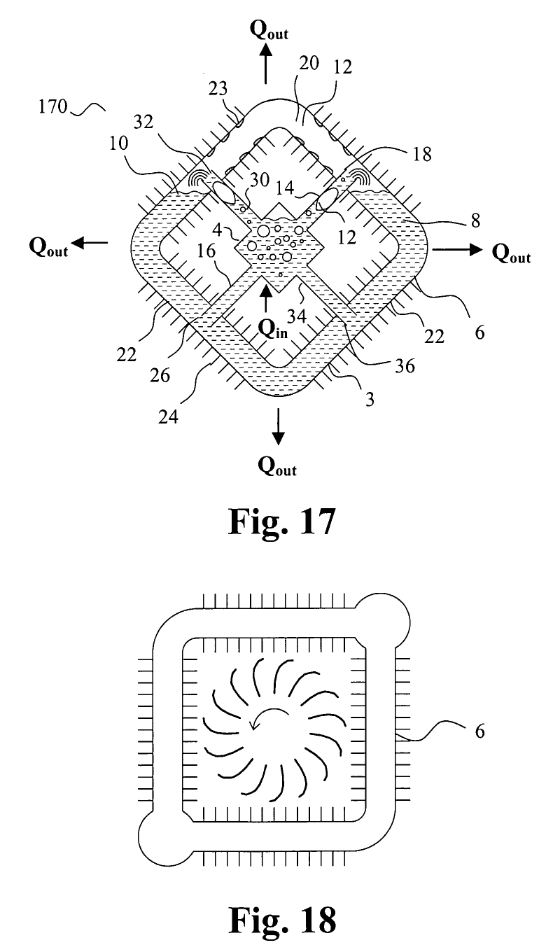

FIG. 17 is a schematic side view of the cooling system of FIG. 16 rotated about 45° clockwise around an axis perpendicular to the plane of the drawing,

FIG. 18 shows a cooling system according to the invention with a cooling fan,

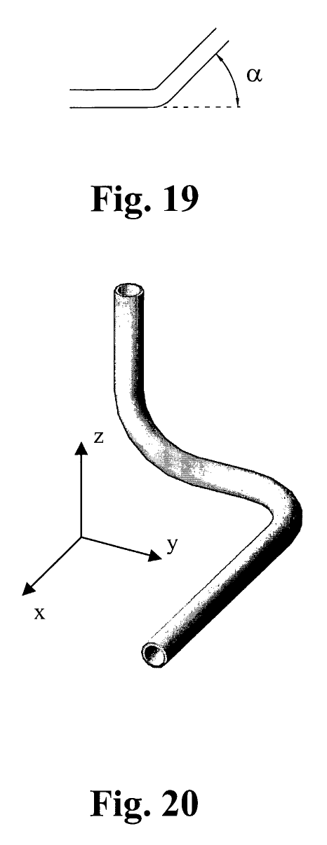

FIG. 19 is a schematic view of a part adapted to function as a bubble pump,

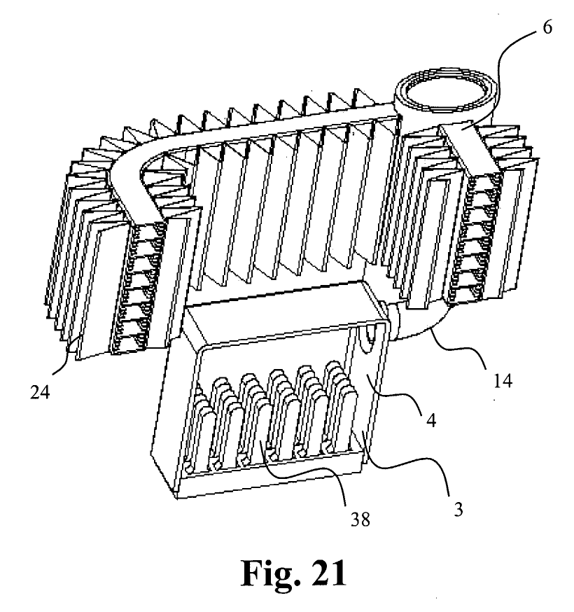

FIG. 20 shows an alternative embodiment of a part adapted to function as a bubble pump,

FIG. 21 is a perspective view of a cross section of an embodiment of the cooling system according to the invention,

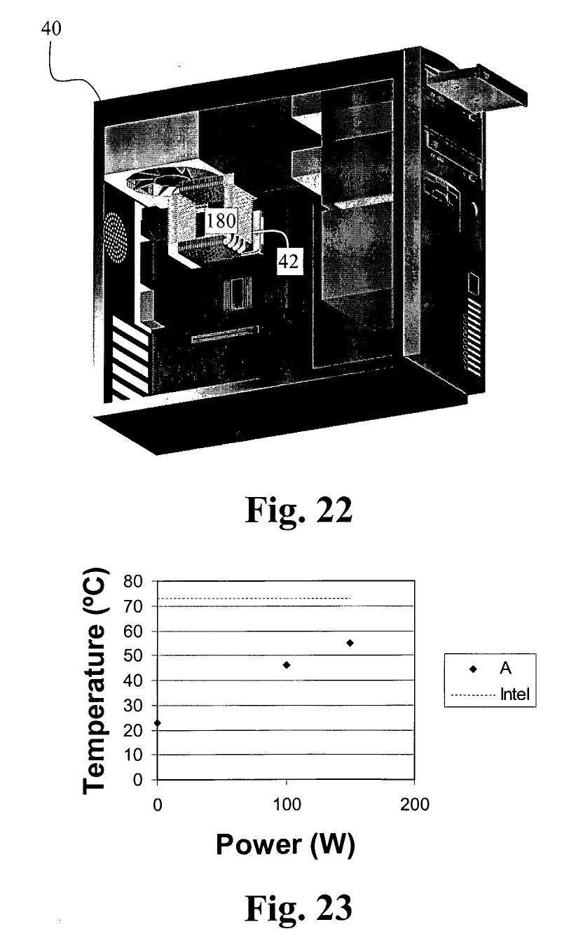

FIG. 22 shows a cooling system according to the present invention employed in a PC for cooling of electronic components, and

FIG. 23 shows test results obtained for the embodiment illustrated in FIG. 1

The same reference number denotes the same elements in the different embodiments of the figures, and elements that are explained in connection with one figure may not be explained further in connection with other figures.

FIG. 1-5 is a schematic side view of a cooling system according to the invention. FIG. 1 shows the cooling system in a first operating angular orientation, FIG. 2 shows the cooling system in a second operating angular orientation, FIG. 3 shows the cooling system in a third operating angular orientation, FIG. 4 shows the cooling system in a fourth operating angular orientation, and FIG. 5 shows the cooling system in a fifth operating angular orientation. FIG. 2 shows the cooling system of FIG. 1 rotated 90° clockwise around an axis perpendicular to the plane of the drawing, FIG. 3 shows the cooling system of FIG. 1 rotated 180° clockwise around an axis perpendicular to the plane of the drawing, FIG. 4 shows the cooling system of FIG. 1 rotated 270° clockwise around an axis perpendicular to the plane of the drawing, and FIG. 5 shows the cooling system of FIG. 1 rotated 315° clockwise around an axis perpendicular to the plane of the drawing.

FIG. 1 shows a cooling system 100 according to the present invention in a first operating angular orientation. The cooling system 100 operates by circulating a cooling fluid 2 and comprises a hollow member 3 comprising a first heat-receiving part 4 for receiving heat Qᵢₙ from at least one heat-emitting element (not shown), and a heat-emitting part 6 for emission of heat Qₒᵤₜ to the surroundings. The hollow member 3 is substantially filled with cooling fluid 2. Cooling fluid 2 in liquid form 8 is indicated by the horizontal, broken lines, while the circles or the ovals and hollow member space above the liquid level 10 in the system indicate cooling fluid in vapor form 12. Further, the system comprises a first part 14 and a second part 16. In the first operating angular orientation the first part 14 is adapted for functioning as a bubble pump for moving liquid and gaseous cooling fluid from the first heat-receiving part 4 to the heat-emitting part 6. Arrows indicate the flow direction of the cooling fluid.

The first heat-receiving part 4 forms an enclosure having a first port 17a connected to the tubular first part 14 and a second port 17b connected to the tubular second part 16. In the first operating angular orientation, the first port 17a functions as an outlet for cooling fluid out of the first heat-receiving part 4 and the second port 17b functions as an inlet for cooling fluid into the first heat-receiving part 4.

In this embodiment, the cooling fluid comprises two fluids having different boiling points. A first fluid has a low boiling point, and a second fluid has a high boiling point. The first fluid is selected with a boiling point suitable for cooling of the heat-emitting elements. In this embodiment the first fluid is ethanol and the second fluid is water. The pressure in the closed cooling system is adjusted, e.g. during manufacturing of the system, so that the first fluid with the low boiling point boils at a desired temperature.

The cooling system receives heat energy Qᵢₙ supplied to the first heat-receiving part 4 heating the cooling fluid 2 of the system. When the cooling fluid 2 reaches the boiling point temperature of the first fluid, a part of the cooling fluid, mainly the first fluid with the low boiling point, evaporates. The evaporated cooling fluid 12 flows into the first part 14 in the form of bubbles. In the first part 14, and in general in a part functioning as a bubble pump, bubbles created during heating of the cooling fluid in liquid form at the heat-receiving part(s) combine to larger bubbles that substantially fill up the cross section of the part functioning as a bubble pump thereby pushing liquid above the bubbles upward in the part functioning as a bubble pump.

The cooling fluid comprising evaporated (i.e. gaseous) cooling fluid and heated, liquid cooling fluid leaves the first part 14 at a first outlet 18. The first outlet 18 resides above the liquid level 10 in the system, whereby reflux of cooling fluid into the part functioning as a bubble pump is avoided. The heat-emitting part 6 comprises a portion adapted to operate as a condenser 20 and a portion adapted to operate as a radiator 22. The evaporated cooling fluid 12 condenses in the portion adapted to operate as a condenser 20, and the condensed cooling fluid 23 may be cooled further. The liquid cooling fluid 8 is cooled in the portion adapted to operate as a radiator 22.

The heat Qₒᵤₜ emitted to the surroundings is the sum of energy from condensation of evaporated cooling fluid and from cooling of liquid cooling fluid.

In the equilibrium state of the cooling system, the heat Qᵢₙ, which the system receives, equals the heat Qₒᵤₜ, which the heat-emitting part comprising the portions adapted to operate as radiator and/or condenser emits to the surroundings.

The cooling fluid 2 flows from the heat-emitting part 6 into the first heat-receiving part 4 through a second part 16. Thus, the first part 14 functions as a bubble pump creating a flow of cooling flow in liquid and vapor form from the first heat-receiving part 4 through the first part 14 to the heat-emitting part 6, the cooling fluid 2 returning to the first heat-receiving part 4 through the second part 16. The condensed cooling fluid 23 is mixed with the liquid cooling fluid 8 before reentering the first heat-receiving part 4.

The outer part of the heat-emitting part 6 is provided with ribs or fins 24 to enhance heat exchange with the surroundings. Moreover, the interior of the heat-emitting part 6, as well as the interior of the first heat-receiving part 4 may be provided with ribs, fins, rods, or the like to enhance heat exchange.

In FIG. 2 the cooling system 100 is in a second operating angular orientation. The second operating angular orientation results from rotating the cooling system 100 of FIG. 1 about 90° clockwise around an axis perpendicular to the plane of the drawing, i.e. typically a horizontal axis. In the second operating angular orientation the second part 16 is adapted for functioning as a bubble pump for moving liquid and gaseous cooling fluid from the first heat-receiving part 4 to the heat-emitting part 6. The second part 16 has a second outlet 26 that resides above the liquid level 10 of the system in the second operating angular orientation. In this operating angular orientation the first part 14 operates as an inlet pipe to the first heat-receiving part 4.

In the second operating angular orientation, the first port 17a functions as an inlet for cooling fluid into the first heat-receiving part 4 and the second port 17b functions as an outlet for cooling fluid out of the first heat-receiving part 4.

It should be noted that the portion at A functioning as a condenser in the first operating angular orientation functions as a radiator in the second operating angular orientation while the portion at B functioning as a radiator in the first angular orientation functions as a condenser in the second angular orientation.

In FIG. 3 the cooling system 100 is in a third operating angular orientation. The third operating angular orientation results from rotating the cooling system 100 in FIG. 1 about 180° clockwise around an axis perpendicular to the plane of the drawing. In the third operating angular orientation, the second part 16 is adapted for functioning as a bubble pump for moving liquid and gaseous cooling fluid from the first heat-receiving part 4 to the heat-emitting part 6. The second outlet 26 resides above the liquid level 10 of the system in the third operating angular orientation. In this operating angular orientation the first part 14 operates as an inlet pipe to the first heat-receiving part 4.

It should be noted that the portion at A functioning as a condenser in the first operating angular orientation functions as a radiator in the third operating angular orientation while the portion at B functioning as a radiator in the first angular orientation also functions as a radiator in the third angular orientation.

In FIG. 4 the cooling system 100 is in a fourth operating angular orientation. The fourth operating angular orientation results from rotating the cooling system 100 of FIG. 1 about 270° clockwise around an axis perpendicular to the plane of the drawing. In the fourth operating angular orientation, the first part 14 is adapted for functioning as a bubble pump for moving liquid and gaseous cooling fluid from the first heat-receiving part 4 to the heat-emitting part 6. The first outlet 18 resides above the liquid level 10 of the system in the fourth operating angular orientation. In this operating angular orientation the second part 16 operates as an inlet pipe to the first heat-receiving part 4.

It should be noted that the portion at A functioning as a condenser in the first operating angular orientation functions as a radiator in the fourth operating angular orientation while the portion at B functioning as a radiator in the first angular orientation also functions as a radiator in the fourth angular orientation.

In FIG. 5 the cooling system 100 is in a fifth operating angular orientation. In the fifth operating angular orientation, the first part 14 is adapted for functioning as a bubble pump for moving liquid and gaseous cooling fluid from the first heat-receiving part 4 to the heat-emitting part 6. The first outlet 18 resides above the liquid level 10 of the system in the fifth operating angular orientation. In this operating angular orientation the second part 16 operates as an inlet pipe to the first heat-receiving part 4.

FIG. 6 shows the cooling system 100 in the second operating position as shown in FIG. 2. The liquid level 10 of the system is higher, thus the liquid cooling fluid constitutes a larger percentage by volume of the volume of the hollow member.

FIG. 7 is a schematic side view of a second embodiment 110 of the cooling system according to the invention. The second embodiment may also be operated when rotated around an axis perpendicular to the plane of the drawing like the cooling system 100 shown in FIG. 1-5

FIG. 8 is a schematic side view of a third embodiment 120 of the cooling system according to the invention. The third embodiment may also be operated when rotated around an axis perpendicular to the plane of the drawing like the cooling system 100 shown in FIG. 1-5.

FIG. 9 is a schematic side view of a fourth embodiment 130 of the cooling system according to the invention. In this embodiment, the parts 14, 16 adapted for functioning as bubble pumps in different angular orientations are substantially straight tubes.

FIGS. 10-11 are schematic side views of a fifth embodiment 140 of the cooling system according to the invention. FIG. 11 shows the cooling system of FIG. 10 rotated 180° clockwise around an axis perpendicular to the plane of the drawing.

FIG. 12 is a schematic side view of a sixth embodiment 150 of the cooling system according to the invention. The embodiment of FIG. 12 comprises a first heat-receiving part 4 and a second heat-receiving part 28. The second heat-receiving part 28 is connected upstream the first heat-receiving part 4, but may also be connected downstream the first heat-receiving part 4. This embodiment can, just as the other embodiments, operate in multiple angular orientations.

FIGS. 13-14 is a schematic side view of a seventh embodiment 160A of the cooling system according to the invention. FIG. 14 shows the cooling system of FIG. 13 rotated 180° clockwise around an axis perpendicular to the plane of the drawing.

The cooling system of FIGS. 13-14 further comprises a third part 30 having an outlet 32. In a first operating angular orientation as shown in FIG. 13 the first part 14 functions as a bubble pump for moving liquid and gaseous cooling fluid from the first heat-receiving part 4 to the heat-emitting part 6. The second part 16 and the third part 30 operate as an inlet pipe to the first heat-receiving part 4. In a second operating angular orientation as shown in FIG. 14 the second part 16 and the third part 30 function as a bubble pump for moving liquid and gaseous cooling fluid from the first heat-receiving part 4 to the heat-emitting part 6. The first part 14 operates as an inlet pipe to the first heat-receiving part 4. The outlets 26 and 30 reside above the liquid level 10. The first heat-receiving part 4 comprises a third port 31.

FIG. 15 shows an embodiment 160B of the cooling system similar to the embodiment of FIG. 13-14. The third part 30 functions in the illustrated angular orientation as a bubble pump for moving liquid and gaseous cooling fluid from the first heat-receiving part 4 to the heat-emitting part 6. The first part 14 and the second part 16 operate as an inlet pipe to the first heat-receiving part 4.

FIGS. 16-17 is a schematic side view of an eighth embodiment 170 of the cooling system according to the invention. FIG. 17 shows the cooling system of FIG. 16 rotated 45° clockwise around an axis perpendicular to the plane of the drawing.

The cooling system of FIGS. 16-17 further comprises a fourth part 34 having an outlet 36. In a first operating angular orientation as shown in FIG. 16 the first part 14 functions as a bubble pump for moving liquid and gaseous cooling fluid from the first heat-receiving part 4 to the heat-emitting part 6. The second part 16, the third part 30, and the fourth part 34 operate as an inlet pipe to the first heat-receiving part 4. In a second operating angular orientation as shown in FIG. 17 the first part 14 and the third part 30 function as a bubble pump for moving liquid and gaseous cooling fluid from the first heat-receiving part 4 to the heat-emitting part 6. The second part 16 and the fourth part 34 operate as an inlet pipe to the first heat-receiving part 4.

When rotating the cooling system 170 of FIG. 16 around an axis perpendicular to the plane of the drawing, different parts depending on the rotation angle will function as a bubble pump for moving liquid and gaseous cooling fluid from the first heat-receiving part 4 to the heat-emitting part 6. For example, the third part 30 will function as a bubble pump when the cooling system 170 is rotated around 90° clockwise, the third part 30 and the second part 16 will function as a bubble pump when the cooling system is rotated around 135° clockwise, the second part 16 will function as a bubble pump when the cooling system is rotated around 180° clockwise, the second part 16 and the fourth part 34 will function as a bubble pump when the cooling system is rotated around 225° clockwise, the fourth part 34 will function as a bubble pump when the cooling system is rotated 270° clockwise, and the fourth part 34 and the first part 14 will function as a bubble pump when the cooling system is rotated around 315° clockwise.

FIG. 18 shows a cooling system according to the invention with a fan mounted for creating forced convection on the cooling system. The fan may be a radial fan and mounted within the heat-emitting part 6.

FIG. 19 is a schematic view of a part adapted to function as a bubble pump. The part may be bent at an angle α, which may range from 0° to 115, such as around 15°, around 30°, around 45°, around 60°, around 75°, and around 90°. Parts that are bent may function as a bubble pump in a wider range of angular orientations compared to a substantially linear part.

FIG. 20 shows an alternative embodiment of a part adapted function as a bubble pump. A portion of the part extends substantially linearly along an axis parallel to the x-axis. Further, another portion of the part extends substantially linearly along an axis parallel to the y-axis, the y-axis being perpendicular to the x-axis. Finally, yet another portion of the part extends substantially linearly along an axis parallel to the z-axis, the z-axis being perpendicular to the x-axis and the y-axis. A part extending partly along the x-, y-, and z-axis provides a wide angular operating space of the part functioning as a bubble pump, since in any orientation of the part, at least one of the portions will extend in a substantially vertical direction.

FIG. 21 is a perspective view of a cross section of an embodiment of the cooling system according to the invention. The interior of the first heat-receiving part 4 is provided with rods 38 to ensure good heat contact with the cooling fluid in the system. The rods may contact the interior surface of the first heat-receiving part 4 at both ends.

FIG. 22 shows a cooling system 180 according to the present invention employed in a stationary computer 40 for cooling of electronic components, such as microchips, CPU's, semiconductor devices, PSU's, etc., during, and after the operation of the stationary computer. Here, the CPU 42 in the stationary computer is cooled by the cooling system 180.

FIG. 23 shows test results obtained for the embodiment illustrated in FIG. 1. A heat-emitting element generating 100 W and 150 W heat power on a heat-receiving surface of 1.50 cm² was cooled by a cooling system according to the present invention. Measurements of corresponding values of temperature and generated heat power are plotted as data points A. It is seen that the cooling system is capable of cooling a heat-emitting element to temperatures below Intel's Thermal Design Power of 73° C. at 100 W and 150 W. As indicated in the plot, 150 W heat power was removed from the surface of 1.50 cm², which corresponds to a heat density of 100 W/cm² at a temperature of 55° C. Low noise forced cooling was applied. The noise generated from the cooling system was less than 30 dB(A). A thermal resistance of 0.21° C./W was obtained at 150 W generated heat power.

It should be noted that arbitrary features of the different embodiments shown in the different figures could be combined if desired.

1. A closed cooling system for cooling of at least one heat-emitting element by a circulating and evaporating cooling fluid, comprising
at least one hollow member facilitating flow of the cooling fluid, comprising
a first heat-receiving part for receiving heat from the at least one heat-emitting element,
a heat-emitting part for emission of heat absorbed by the heat-receiving part to the surroundings, and
a tubular first part interconnecting the first heat-receiving part and the heat-emitting part, and adapted for functioning, in a first angular orientation of the system, as
a first bubble pump for generation of a fluid flow in the system through the first heat-receiving part and being positioned downstream the first heat-receiving part, and
a tubular second part interconnecting the first heat-receiving part and the heat-emitting part, and adapted for functioning, in a second angular orientation of the system, as
a second bubble pump for generation of a fluid flow in the system through the first heat-receiving part and being positioned downstream the first
heat-receiving part.

2. A cooling system according to claim 1, wherein the at least one hollow member comprises a third part that, in a third angular orientation of the system, is adapted for functioning as a third bubble pump for generation of a fluid flow in the system and being positioned downstream the first heat-receiving part.

3. A cooling system according to claim 1, wherein the at least one hollow member comprises a fourth part that, in a fourth angular orientation of the system, is adapted for functioning as a fourth bubble pump for generation of a fluid flow in the system and being positioned downstream the first heat-receiving part.

4. A cooling system according to claim 1, wherein two or more parts are adapted for functioning as a bubble pump in an operating angular orientation.

5. A cooling system according to claim 1, wherein the second angular orientation results from turning the system in the first angular orientation an angle around a horizontal axis.

6. A cooling system according to claim 1, wherein at least one of the parts adapted for functioning as a bubble pump in a respective angular orientation of the system has an outlet above the liquid level in the cooling system in that orientation.

7. A closed cooling system according to claim 1, wherein the heat-emitting part comprises a portion that is adapted to operate as a radiator in one operating orientation of the cooling system and as a condenser in another operating orientation of the cooling system.

8. A cooling system according to claim 1, wherein the cooling fluid consists of a single fluid.

9. A cooling system according to claim 1, wherein the cooling fluid comprises at least two fluids with different boiling points.

10. A cooling system according to claim 1, wherein a first fluid in the cooling fluid is selected from the group consisting of ethanol, methanol, acetone, ether, and propane.

11. A cooling system according to claim 1, wherein a second fluid in the cooling fluid is selected from the group consisting of water, methanol, ethanol, acetone, and glycol.

12. A cooling system according to claim 1, wherein a heat-emitting element is integrated in the first heat-receiving part and is in direct contact with the cooling fluid in the cooling system.

13. A cooling system according to claim 1, wherein the first heat-receiving part comprises a plurality of separated liquid chambers.

14. A cooling system according to claim 1, further comprising a second heat-receiving part for accommodation of one or more heat-emitting elements.

15. A cooling system according to claim 1, wherein the first heat-receiving part forms an enclosure having at least a first port and a second port.

16. A cooling system according to claim 15, wherein the first port is connected to the first part and the second port is connected to the second part

17. An electronic device having one or more elements to be cooled during the operation of the electronic device, wherein the electronic device comprises a cooling system according to claim 1.

18. Use of a cooling system according to claim 1 for cooling of electronic components.
